(19) United States
(12) Patent Application Publication
(10) Pub. No.: US 2019/0157253 A1
(43) Pub. Date: May 23, 2019

(54) Circuit Systems Having Memory Modules With Reverse Orientations

(71) Applicant: Intel Corporation, Santa Clara, CA (US)

(72) Inventors: David Browning, Portland, OR (US); John Eley, Portland, OR (US)

(73) Assignee: Intel Corporation, Santa Clara, CA (US)

(21) Appl. No.: 16/254,403

(22) Filed: Jan. 22, 2019

(51) Int. Cl. H01L 25/18; H01L 23/00

(52) U.S. Cl. CPC H01L 25/18; H01L 24/17; H01L 24/16; G06F 13/1689; H01L 2224/16225; H01L 2924/1434; H01L 2924/1431; H01L 2224/17181

(57) ABSTRACT

A circuit system includes an integrated circuit package, first and second memory modules, and a base circuit board. The integrated circuit package houses a main integrated circuit die. The first memory module has a first circuit board and first memory integrated circuit dies coupled to the first circuit board. The second memory module has a second circuit board and second memory integrated circuit dies coupled to the second circuit board. The base circuit board is coupled to the integrated circuit package and to the first and second memory modules. The base circuit board includes conductors that couple the integrated circuit package to the first and second memory modules. The second memory module has a reverse orientation on the base circuit board relative to the first memory module such that the second memory integrated circuit dies face away from the first memory integrated circuit dies.

### FIELD OF THE DISCLOSURE

The present disclosure relates to electronic circuit systems, and more particularly, to circuit systems having memory modules with reverse orientations.

### BACKGROUND

FIG. 1 illustrates a top down view of a prior art programmable acceleration system 100 that can accelerate tasks for a processor. System 100 includes a field programmable gate array (FPGA) package 101 containing an FPGA integrated circuit (IC) die and four dual in-line memory modules (DIMMs) 102-105. Each of the DIMMs 102-105 includes a series of 8 dynamic random-access memory (DRAM) integrated circuits (ICs) 110. The ICs 110 in DIMMs 102-105 are mounted on printed circuit boards 111-114, respectively. The DIMMs 102-105 have 1-rank single-sided configurations. The DRAM ICs 110 on the DIMMs 102-105 are coupled to the FPGA IC die in package 101 through conductors in circuit boards 111-114, respectively, and through conductors in a base circuit board that is not shown in Figure (FIG. 1.

FIG. 2 illustrates additional details of a portion of system 100, including FPGA package 101 and DIMMs 102-103. The input/output (I/O) pads of each DRAM IC in each of the DIMMs, including DIMMs 102 and 103, are organized into four groups that are identified as 4 bytes, command address, ECC, and 4 bytes. The I/O pads for one DRAM IC in each of DIMMs 102-103 is shown in FIG. 2. The DRAM IC I/O pads in the 4 bytes groups, command address groups, ECC groups, and 4 bytes groups are used to transmit and receive 4 bytes of data signals, command and address signals, error correction code (ECC) signals, and 4 bytes of data signals, respectively.

FPGA package 101 has I/O pads for two channels that are identified as channel 0 and channel 1 in FIG. 2. The I/O pads for channels 0 and 1 are used for the transmission of signals to and from DIMMs 102 and 103, respectively. The I/O pads for each channel are organized into four groups identified as 4 bytes, command address (com add), ECC, and 4 bytes in FIG. 2. The I/O pads in each of the 4 bytes groups are used for the transmission of 4 bytes of data signals between the FPGA IC die and the DRAM IC I/O pads in the corresponding 4 bytes groups. The I/O pads in the command address groups are used for the transmission of command and address signals between the FPGA IC die and the DRAM IC I/O pads in the corresponding command address groups. The I/O pads in the ECC groups are used for the transmission of signals indicating bytes of error correction codes (ECC) between the FPGA IC die and the DRAM IC I/O pads in the corresponding ECC groups. The connections through the base circuit board between the groups of FPGA package I/O pads and the corresponding DRAM IC I/O pads are represented by solid line arrows in FIG. 2.

### BRIEF DESCRIPTION OF THE DRAWINGS

FIG. 1 illustrates a prior art programmable acceleration system that can accelerate tasks for a processor.

FIG. 2 illustrates additional details of a portion of the system of FIG. 1, including an FPGA package and DIMMs.

FIG. 3 illustrates a top down view of an example of a circuit system including memory modules having memory integrated circuits (ICs) that are facing away from each other and the direction of airflow across the circuit system as shown by horizontal arrows, according to an embodiment.

FIG. 4 illustrates a side view of the circuit system of FIG. 3, according to an embodiment.

FIG. 5 illustrates further details of the circuit system of FIG. 3 including signal paths between the IC package and the memory IC dies in the memory modules from a top down view, according to an embodiment.

FIGS. 6A-6D illustrate examples of changes to signal routing layers of the base circuit board in the circuit system of FIG. 3 that can be made to accommodate the reverse orientation of a memory module, according to an embodiment.

FIG. 7 illustrates an exemplary embodiment of a programmable logic integrated circuit (IC) that can be used in embodiments disclosed herein.

### DETAILED DESCRIPTION

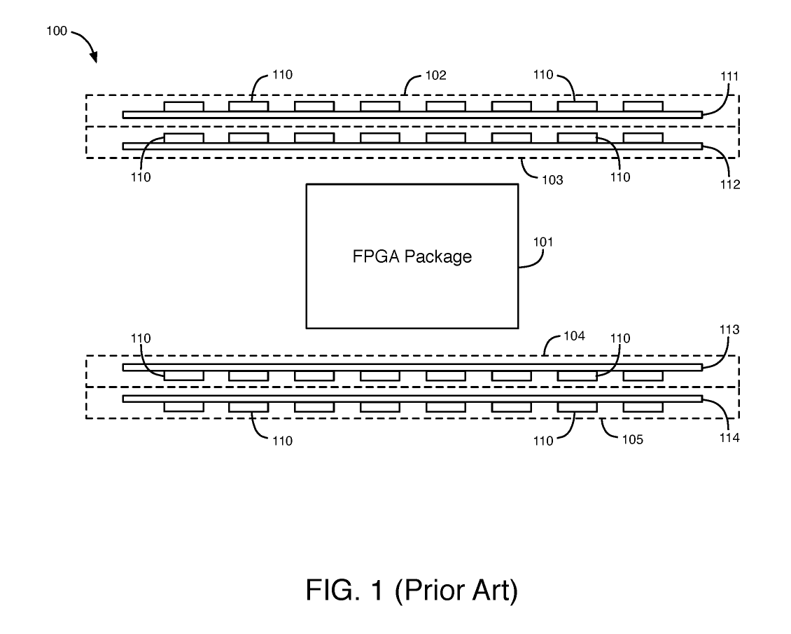

FPGA programmable acceleration system 100 shown in FIG. 1 has many components that generate heat. For example, DIMMs 102-105 are a significant source of heat in system 100. Because DIMMs 102-103 and 104-105 are close together in system 100, there is limited space for improved cooling techniques. When all 4 DIMMs 102-105 are populated with memory devices 110 in system 100, one of the DIMMs on each side of system 100 has memory devices 110 that are in a gap between two DIMMs, as shown, for example, in FIG. 1 between DIMMs 102 and 103 and between DIMMs 104 and 105. These gaps are very constrained for airflow and are typically where the hottest memory devices 110 are located.

In addition, the maximum junction temperature of the DIMMs 102-105 tends to be much lower than the maximum temperature of the FPGA IC die in package 101. The maximum junction temperature of the DIMMs 102-105 can, for example, be in the range of 60-70° C., while the FPGA IC die can operate at a temperature of 100° C. and above. A cooling system for circuit system 100 that keeps the DIMMs below their maximum junction temperature would limit the performance of the FPGA IC die and negate any improved FPGA cooling solution.

According to some embodiments disclosed herein, one of the memory modules on each side of a circuit system has a reverse orientation such that memory integrated circuits (ICs) coupled to the two memory modules on each side of the circuit system are facing away from each other. Because the memory ICs in the memory modules are facing away from each other, the memory ICs in the memory modules are not in a narrow gap between two memory modules. As a result, the memory ICs are naturally exposed to increased airflow, which provides more effective cooling to the memory ICs. The thermal headroom of the memory ICs is increased, and the main IC coupled to the circuit system can take more advantage of higher speed bins and increased performance. The main IC's input/output (I/O) pads and the signal paths in the base circuit board of the circuit system can be arranged to allow for the memory ICs in the memory modules to be facing away from each other, as disclosed in further detail herein.

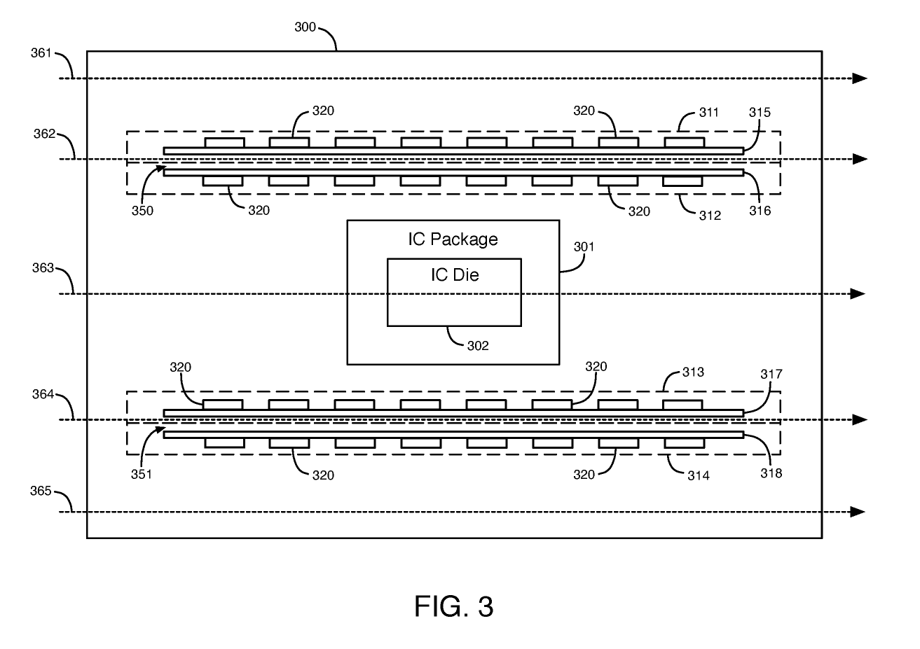

FIG. 3 illustrates a top down view of an example of a circuit system 300 including memory modules having memory integrated circuits (ICs) that are facing away from each other, according to an embodiment. Circuit system 300 of Figure (FIG. 3 includes an integrated circuit (IC) package 301 and four memory modules 311-314. IC package 301 includes a main integrated circuit (IC) die 302. IC die 302 can be, for example, a programmable logic IC, such as a field programmable gate array (FPGA), a processor IC, such as a central processing unit or a microprocessor, a graphics processing unit (GPU), or another type of IC.

Each of the memory modules 311-314 includes 8 memory integrated circuit (IC) dies 320. In addition, each of the memory modules 311-314 includes a printed circuit board. Specifically, memory modules 311-314 include printed circuit boards (PCBs) 315-318, respectively. The ICs 320 in memory modules 311-314 are mounted on printed circuit boards 315-318, respectively. Memory modules 311-314 have 1-rank single-sided configurations with memory ICs 320 only on one side of their respective PCBs 315-318. Memory modules 311-314 can be, for example, dual in-line memory modules (DIMMs). The memory IC dies 320 in each of the memory modules 311-314 are coupled to IC die 302 through electrical conductors in PCBs 315-318, a base circuit board, and IC package 301.

In the top down view of FIG. 3, memory module 312 has been rotated 180° relative to DIMM 103 of FIG. 1, and memory module 313 has been rotated 180° relative to DIMM 104 of FIG. 1. As a result, memory module 312 has a reverse orientation on the base circuit board relative to memory module 311 such that the memory IC dies 320 in memory module 312 and the memory IC dies 320 in memory module 311 face away from each other in opposite directions. As shown in FIG. 3, the memory IC dies 320 in memory module 312 are facing IC package 301 and are not in the gap 350 between memory modules 311-312. Also, memory module 313 has a reverse orientation on the base circuit board relative to memory module 314 such that the memory IC dies 320 in memory module 313 and the memory IC dies 320 in memory module 314 face away from each other in opposite directions. The memory IC dies 320 in memory module 313 are facing IC package 301 and are not in the gap 351 between memory modules 313-314. The memory IC dies 320 in memory modules 312 and 313 are in a more thermally exposed region of system 300 that provides the memory IC dies in modules 312-313 with a higher natural thermal cooling capability. The positions of the memory IC dies 320 in system 300 allows for naturally increased airflow around the memory IC dies 320 in memory modules 312-313, which provides more effective cooling to the memory IC dies 320 compared to system 100. The dotted arrows 361-365 in FIG. 3 show examples of the direction of airflow in system 300. The gap 350 between modules 311 and 312 has limited exposure to the airflow, and the gap 351 between modules 313 and 314 also has limited exposure to airflow. The limited airflow through gaps 350 and 351 is represented by arrows 362 and 364, respectively. In some embodiments, the additional thermal solution enhancements of system 300 can be leveraged to increase their cooling capability through a direct thermal solution connection or air-direction features.

According to another embodiment, the memory modules 311 and 314 can each be rotated 180° to a reverse orientation instead of rotating memory modules 312-313 to cause memory IC dies 320 in memory modules 311 and 312 to face each other and the memory IC dies 320 in memory modules 313 and 314 to face each other. In this embodiment, the memory IC dies 320 in memory modules 311 and 312 are in the gap 350 between these 2 memory modules, and the memory IC dies 320 in memory modules 313 and 314 are in the gap 351 between these 2 memory modules. This embodiment can enable the attachment of shared cooling systems between memory modules 311 and 312 and between memory modules 313 and 314.

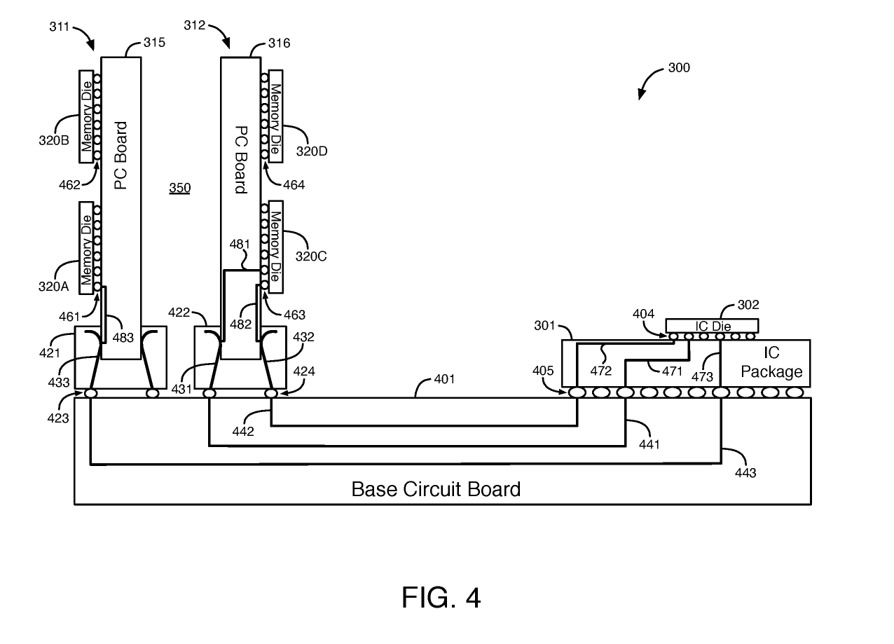

FIG. 4 illustrates a side view of circuit system 300 of FIG. 3, according to an embodiment. FIG. 4 illustrates a portion of system 300 including memory modules 311-312, the base circuit board 401, IC package 301, and IC die 302. As shown in FIG. 4, memory module 312 is parallel to memory module 311, and memory modules 311-312 are perpendicular to the base circuit board 401.

IC die 302 is coupled to IC package 301 through conductive solder bumps 404. IC package 301 is coupled to base circuit board 401 through conductive solder balls 405 in a ball grid array (BGA). Memory module 311 includes printed circuit board (PCB) 315 and 2 memory IC dies 320A-320B. Memory module 312 includes PCB 316 and 2 memory IC dies 320C-320D. The memory IC dies 320A and 320B are coupled to PCB 315 through solder bumps 461-462, respectively. The memory IC dies 320C and 320D are coupled to PCB 316 through solder bumps 463-464, respectively. Solder bumps 461-464 are connected to the I/O pads of memory IC dies 320A-320D, respectively. The additional memory IC dies 320 in memory modules 311-312 are not shown in FIG. 4.

Circuit system 300 also includes memory connectors 421-422. Portions of PCBs 315 and 316 are inserted into memory connectors 421 and 422, respectively, as shown in FIG. 4. PCBs 315 and 316 are coupled to base circuit board 401 through conductors in connectors 421-422, respectively. The conductors in connector 421 are coupled to conductors in base circuit board 401 through solder balls 423. The conductors in connector 422 are coupled to conductors in base circuit board 401 through solder balls 424.

Conductors in IC package 301, base circuit board 401, connectors 421-422, and PCBs 315-316 as well as solder bumps/balls 404, 405, 423-424, and 461-464 couple IC die 302 to memory IC dies 320A-320D. For example, a first conductive I/O pad of IC die 302 is coupled to a first conductive I/O pad of memory IC die 320C through one of solder bumps 404, conductor 471 in IC package 301, one of solder balls 405, conductor 441 in base circuit board 401, one of solder balls 424, conductor 431 in connector 422, and conductor 481 in PCB 316. As another example, a second conductive I/O pad of IC die 302 is coupled to a second conductive I/O pad of memory IC die 320C through a second one of solder bumps 404, conductor 472 in IC package 301, a second one of solder balls 405, conductor 442 in base circuit board 401, a second one of solder balls 424, conductor 432 in connector 422, and conductor 482 in PCB 316. As yet another example, a third conductive I/O pad of IC die 302 is coupled to a first conductive I/O pad of memory IC die 320A through a third one of solder bumps 404, conductor 473 in IC package 301, a third one of solder balls 405, conductor 443 in base circuit board 401, one of solder balls 423, conductor 433 in connector 421, and conductor 483 in PCB 315.

As shown in FIG. 4, the memory IC dies 320C-320D in memory module 312 are facing IC package 301 and are not in the gap 350 between memory modules 311-312. The memory IC dies 320C-320D in memory module 312 are in a more thermally exposed region of system 300 that allows for naturally increased airflow around the memory IC dies 320C-320D, which provides the memory IC dies in module 312 with a higher natural thermal cooling capability. As a result, circuit system 300 provides more effective cooling to the memory ICs 320 compared to system 100.

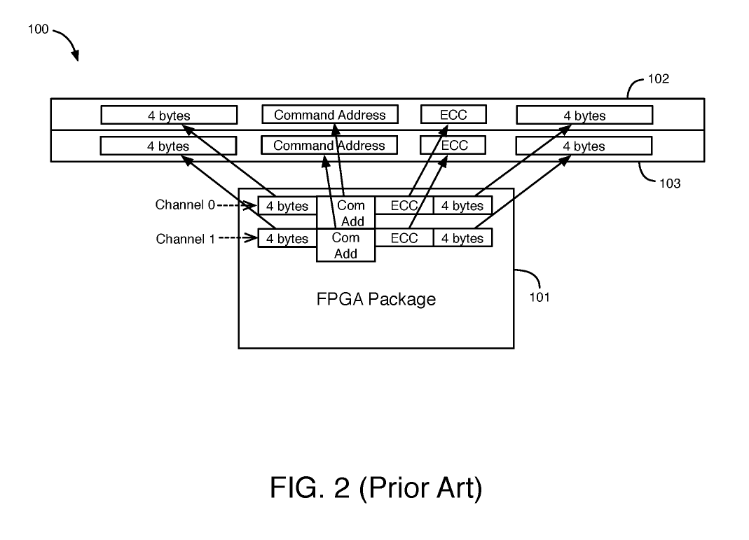

In circuit system 300, the signal routing paths between IC die 302 and the memory IC dies 320 in memory module 312 are changed to accommodate the reverse orientation of memory module 312 relative to memory module 311. As shown in FIG. 2, system 100 is designed such that the signals transmitted to and from DIMMs 102-103 are organized in the same order in each channel. However, in circuit system 300, the order of the signal paths in one of the channels is reversed to accommodate the reverse orientation of the corresponding memory module, as disclosed in further detail below.

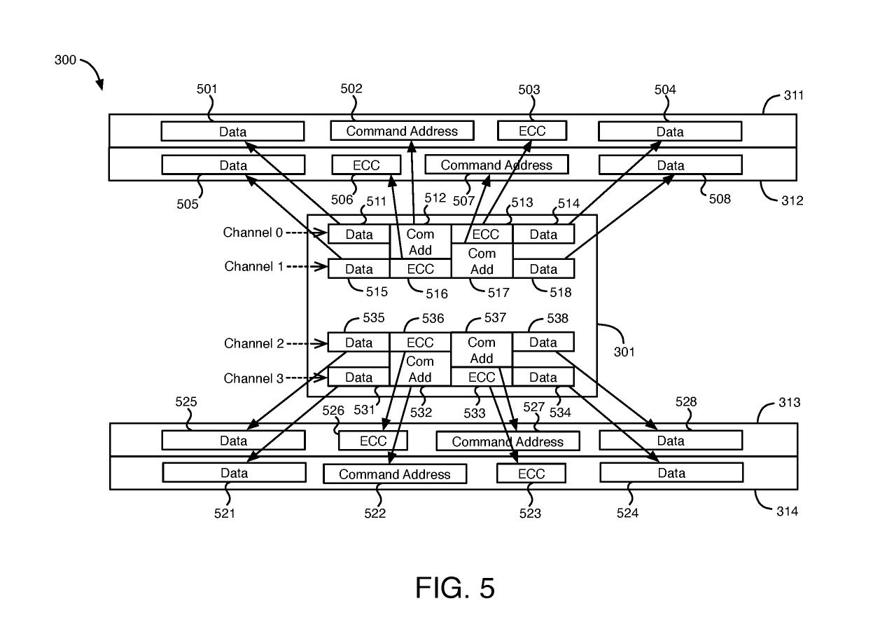

FIG. 5 illustrates further details of circuit system 300 including signal paths between IC package 301 and the memory IC dies 320 in memory modules 311-314, according to an embodiment. Each of the memory IC dies 320 in the memory modules 311-314 receives and/or transmits data signals, command and address signals, and error correction code signals. In the example of FIG. 5, a memory IC die 320 in memory module 311 receives and/or transmits data signals through input/output (I/O) pads 501, command and address signals through I/O pads 502, error correction code (ECC) signals through I/O pads 503, and data signals through I/O pads 504. A memory IC die 320 in memory module 312 receives and/or transmits data signals through I/O pads 505, ECC signals through I/O pads 506, command and address signals through I/O pads 507, and data signals through I/O pads 508. A memory IC die 320 in memory module 313 receives and/or transmits data signals through I/O pads 525, ECC signals through I/O pads 526, command and address signals through I/O pads 527, and data signals through I/O pads 528. A memory IC die 320 in memory module 314 receives and/or transmits data signals through I/O pads 521, command and address signals through I/O pads 522, ECC signals through I/O pads 523, and data signals through I/O pads 524.

FIG. 5 also illustrates 16 groups 511-518 and 531-538 of I/O pads on a surface of IC package 301. The groups 511-518 and 531-538 of I/O pads are organized into 4 rows that correspond to 4 channels in the IC die 302. The channels are identified as channels 0, 1, 2, and 3 in FIG. 5. Each row includes four groups of I/O pads on a surface of IC package 301. In other embodiments, IC die 302 can have more channels in addition to the 4 channels in FIG. 5, and IC package 301 can have more I/O pads in addition to the groups of I/O pads shown in FIG. 5. The I/O pads for channels 0, 1, 2, and 3 are used for the transmission of signals to and from memory modules 311, 312, 313, and 314, respectively, as shown by the solid arrows in FIG. 5.

The I/O pads in package 301 for each of the four channels 0-3 are organized into four groups identified as data, command address (com add), and ECC (error correction code) in FIG. 5. As shown in FIG. 5, channel 0 includes data pads 511, command address pads 512, ECC pads 513, and data pads 514. Signals are routed between IC die 302 and memory module 311 through I/O pads 511-514 of package 301. Channel 1 includes data pads 515, ECC pads 516, command address pads 517, and data pads 518. Signals are routed between IC die 302 and memory module 312 through I/O pads 515-518 of package 301. Channel 2 includes data pads 535, ECC pads 536, command address pads 537, and data pads 538. Signals are routed between IC die 302 and memory module 313 through I/O pads 535-538 of package 301. Channel 3 includes data pads 531, command address pads 532, ECC pads 533, and data pads 534. Signals are routed between IC die 302 and memory module 314 through I/O pads 531-534 of package 301.

The I/O pads in groups 511, 515, 535, and 531 are arranged in a first column on a surface of package 301. The I/O pads in groups 512, 516, 536, and 532 are arranged in a second column on the surface of package 301. The I/O pads in groups 513, 517, 537, and 533 are arranged in a third column on the surface of package 301. The I/O pads in groups 514, 518, 538, and 534 are arranged in a fourth column on the surface of package 301.

The I/O pads in data groups 511 and 514 are used for the transmission of data signals between IC die 302 and the memory IC die I/O pads in groups 501 and 504, respectively. The I/O pads in command address group 512 are used for the transmission of command and address signals between IC die 302 and the memory IC die I/O pads in command address group 502. The I/O pads in ECC group 513 are used for the transmission of error correction code (ECC) signals between IC die 302 and the memory IC die I/O pads in ECC group 503.

The I/O pads in data groups 515 and 518 are used for the transmission of data signals between IC die 302 and the memory IC die I/O pads in groups 505 and 508, respectively. The I/O pads in ECC group 516 are used for the transmission of error correction code (ECC) signals between IC die 302 and the memory IC die I/O pads in ECC group 506. The I/O pads in command address group 517 are used for the transmission of command and address signals between IC die 302 and the memory IC die I/O pads in command address group 507. In system 300, the signal paths for channel 1 through the I/O pads in groups 515-518 on IC package 301 are rotated 180° relative to the signal paths for channel 1 through the I/O pads on IC package 101 of FIG. 2 and relative to the signal paths for channel 0 through groups 511-514 in system 300 in order to be aligned with the reverse orientation of memory module 312.

The I/O pads in data groups 535 and 538 are used for the transmission of data signals between IC die 302 and the memory IC die I/O pads in groups 525 and 528, respectively. The I/O pads in ECC group 536 are used for the transmission of error correction code (ECC) signals between IC die 302 and the memory IC die I/O pads in ECC group 526. The I/O pads in command address group 537 are used for the transmission of command and address signals between IC die 302 and the memory IC die I/O pads in command address group 527.

The I/O pads in data groups 531 and 534 are used for the transmission of data signals between IC die 302 and the memory IC die I/O pads in groups 521 and 524, respectively. The I/O pads in command address group 532 are used for the transmission of command and address signals between IC die 302 and the memory IC die I/O pads in command address group 522. The I/O pads in ECC group 533 are used for the transmission of error correction code (ECC) signals between IC die 302 and the memory IC die I/O pads in ECC group 523. In system 300, the signal paths for channel 2 through the I/O pads in groups 535-538 on IC package 301 are rotated 180° relative to the signal paths for channel 3 through the I/O pads in groups 531-534 in order to be aligned with the reverse orientation of memory module 313.

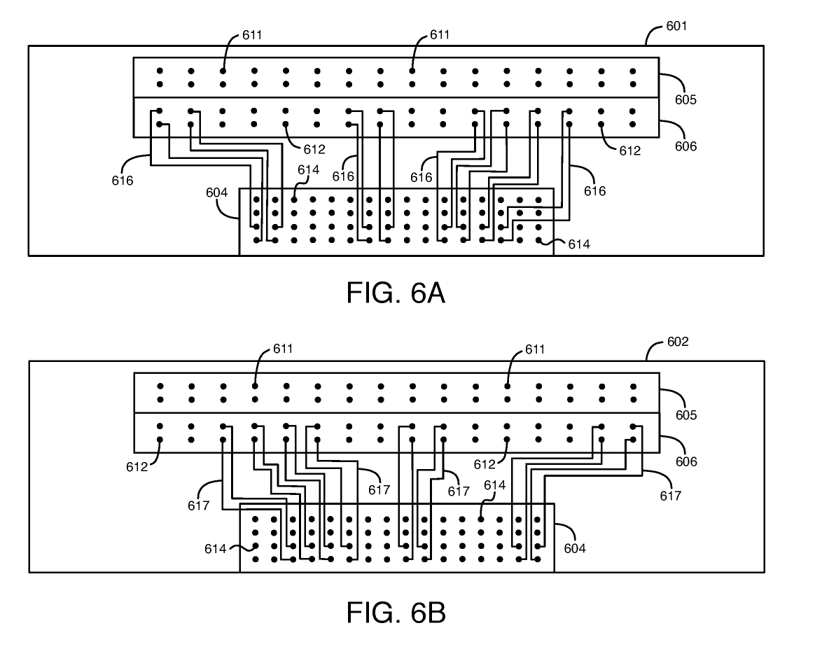

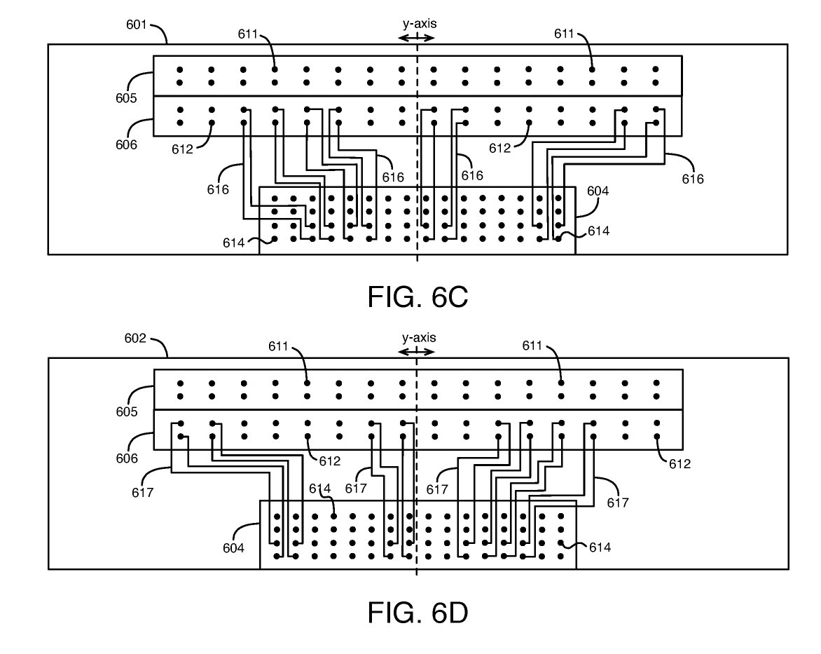

FIGS. 6A-6D illustrate examples of changes to signal routing layers of base circuit board 401 in circuit system 300 that can be made to accommodate the reverse orientation of the memory module 312, according to an embodiment. FIG. 6A illustrates a first signal routing layer 601 in base circuit board 401, and FIG. 6B illustrates a second signal routing layer 602 in base circuit board 401. Signal routing layers 601 and 602 are stacked vertically in board 401 such that one of the signal routing layers 601 or 602 is on top of the other signal routing layer. Each of the first and second signal routing layers 601 and 602 includes 32 conductive pads 611 in region 605 for connecting to memory module 311 through conductive vias in base circuit board 401. Each of the first and second signal routing layers 601 and 602 includes 32 conductive pads 612 in region 606 for connecting to memory module 312 through conductive vias in base circuit board 401. Both the first and second signal routing layers 601-602 include conductive pads 614 in region 604 for connecting to IC package 301 through conductive vias in base circuit board 401. FIG. 6A shows 16 conductive traces 616 that connect 16 of the conductive pads 614 to 16 of the conductive pads 612 in region 606. FIG. 6B shows 16 conductive traces 617 that connect a different set of 16 of the conductive pads 614 to the remaining 16 of the conductive pads 612 in region 606. The conductive pads 614 that are connected to conductive traces 616-617 are connected through conductive vias in board 401 to the I/O pads in channel 1 of IC package 301.

FIGS. 6A-6B illustrate the locations of the conductive traces 616-617, respectively, prior to being rotated 180°. FIGS. 6C-6D illustrate the locations of the conductive traces 616-617, respectively, after being rotated 180° along a vertical y-axis that is shown by vertical dotted lines in FIGS. 6C-6D. Conductive traces 616 have been rotated 180° along the vertical y-axis in FIG. 6C relative to the locations of the conductive traces 616 shown in FIG. 6A. Conductive traces 617 have been rotated 180° along the vertical y-axis in FIG. 6D relative to the locations of the conductive traces 617 shown in FIG. 6B. By rotating the conductive traces 616-617 180° along the vertical y-axis in each of layers 601 and 602, the connections between the I/O pads of channel 1 and the I/O pads of the memory IC dies 320 in memory module 312 are preserved after rotating memory module 312 to the reverse orientation. For example, rotating the conductive traces 616-617 180° allows the I/O pads in ECC group 516 and command address group 517 in channel 1 to connect to the memory IC die I/O pads in ECC group 506 and command address group 507, respectively, in memory module 312. Conductive traces in signal routing layers of board 401 that connect I/O pads in channel 2 to memory module 313 are also rotated 180° along the y-axis to preserve the connections between the I/O pads in groups 535-538 and the I/O pads in groups 525-528, respectively, of memory module 313. As a result, each I/O pad on package 301 is connected to the same I/O pad of the same memory IC die 320 through board 401 after memory modules 312-313 are rotated 180° to their reverse orientations.

In some embodiments, IC die 302 can be a programmable logic IC, such as an FPGA. The signal paths for channel 1 through the I/O pads in groups 515-518 and the signal paths for channel 2 through the I/O pads in groups 535-538 can, for example, be rotated 180° to reverse orientations as shown in FIG. 5 by reconfiguring the configurable circuit blocks in the programmable IC die 302 that generate the signals transmitted through these I/O pads. For example, configurable circuit blocks that previously generated command and address signals that were routed through I/O pads in groups 516 and 536 can be reconfigured to generate ECC signals that are routed through I/O pads in groups 516 and 536. As another example, configurable circuit blocks that previously generated ECC signals that were routed through I/O pads in groups 517 and 537 can be reconfigured to generate command and address signals that are routed through I/O pads in groups 517 and 537. As another example, the signal paths for channels 1 and 2 can be rotated 180° to reverse orientations as shown in FIG. 5 by reconfiguring configurable routing circuitry in the programmable logic IC 302.

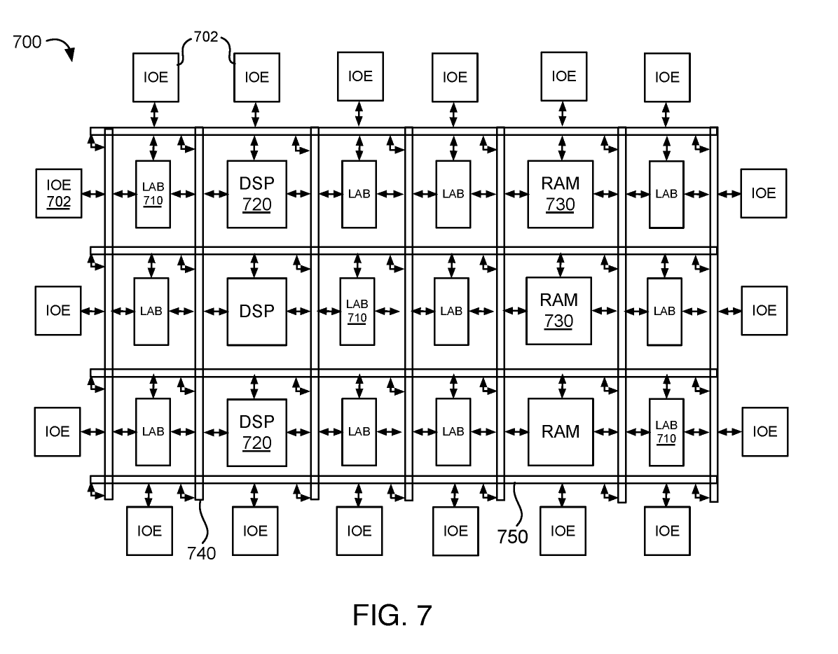

FIG. 7 illustrates an exemplary embodiment of a programmable logic integrated circuit (IC) 700 that can be used with embodiments disclosed herein. For example, programmable logic IC 700 can be IC die 302 shown in FIGS. 3-4. If IC die 302 is a programmable logic IC, such as IC 700, circuit system 300 can, for example, be used to accelerate requests from a processor IC. As shown in FIG. 7, the programmable logic integrated circuit (IC) 700 includes a two-dimensional array of configurable functional circuit blocks, including configurable logic array blocks (LABs) 710 and other functional circuit blocks, such as random access memory (RAM) blocks 730 and digital signal processing (DSP) blocks 720. Functional blocks such as LABs 710 may include smaller configurable regions (e.g., logic elements, logic blocks, or adaptive logic modules) that receive input signals and perform custom logic functions on the input signals to produce output signals. If desired, the functional blocks of an integrated circuit can be arranged in more levels or layers in which multiple functional blocks are interconnected to form still larger blocks. Other device arrangements may use functional blocks that are not arranged in rows and columns.

In addition, programmable logic IC 700 has input/output elements (IOEs) 702 for driving signals off of programmable logic IC 700 and for receiving signals from other devices. Each of the IOEs 702 includes one or more input buffers, one or more output buffers, and one or more I/O pads. Input/output elements 702 may include parallel input/output circuitry, serial data transceiver circuitry, differential receiver and transmitter circuitry, or other circuitry used to connect one integrated circuit to another integrated circuit. As shown, input/output elements 702 may be located around the periphery of the chip. If desired, the programmable logic IC 700 may have input/output elements 702 arranged in different ways. For example, input/output elements 702 may form one or more columns, rows, or islands of input/output elements that may be located anywhere on the programmable logic IC 700.

The programmable logic IC 700 also includes programmable interconnect circuitry in the form of vertical routing channels 740 (i.e., interconnects formed along a vertical axis of programmable logic IC 700) and horizontal routing channels 750 (i.e., interconnects formed along a horizontal axis of programmable logic IC 700), each routing channel including at least one track to route at least one wire.

Note that other routing topologies, besides the topology of the interconnect circuitry depicted in FIG. 7, may be used. For example, the routing topology may include wires that travel diagonally or that travel horizontally and vertically along different parts of their extent as well as wires that are perpendicular to the device plane in the case of three dimensional integrated circuits. The driver of a wire may be located at a different point than one end of a wire.

Programmable logic IC 700 also contains programmable memory elements (e.g., in RAMs 730 or in LABs 710). The programmable memory elements can be loaded with configuration data via input/output elements (IOEs) 702. Once loaded, the programmable memory elements each provide a corresponding static control signal that controls the operation of a logic circuit in an associated configurable functional block (e.g., LABs 710, DSP blocks 720, RAM blocks 730, and/or input/output elements 702).

In a typical scenario, the outputs of the loaded programmable memory elements are applied to the gates of metal oxide semiconductor field effect transistors (MOSFETs) in functional blocks (e.g., any of LAB blocks 710, DSP blocks 720, and RAM blocks 730) to turn certain transistors on or off and thereby configure the logic circuits in the functional blocks including the routing paths. Configurable logic circuit elements that can be controlled in this way include parts of multiplexers (e.g., multiplexers used for forming routing paths in interconnect circuits), look-up tables, logic arrays, AND, OR, NAND, and NOR logic gates, pass gates, etc.

The programmable memory elements can be organized in a configuration memory array including rows and columns. A data register that spans across all columns and an address register that spans across all rows may receive configuration data. The configuration data may be shifted onto the data register. When the appropriate address register is asserted, the data register writes the configuration data to the configuration memory bits of the row of the configuration memory array that was designated by the address register.

In certain embodiments, programmable logic IC 700 can include configuration memory that is organized in sectors, whereby a sector may include the configuration RAM bits that specify the functions and/or interconnections of the subcomponents and wires in or crossing that sector. Each sector can include separate data and address registers and configurable logic circuits.

The following examples pertain to further embodiments. Example 1 is a circuit system comprising: an integrated circuit package housing a main integrated circuit die; a first memory module comprising a first circuit board and first memory integrated circuit dies coupled to the first circuit board; a second memory module comprising a second circuit board and second memory integrated circuit dies coupled to the second circuit board; and a base circuit board coupled to the integrated circuit package and to the first and second memory modules, wherein the base circuit board comprises conductors that couple the integrated circuit package to the first and second memory modules, and wherein the second memory module has a reverse orientation on the base circuit board relative to the first memory module such that the second memory integrated circuit dies face away from the first memory integrated circuit dies.

In Example 2, the circuit system of Example 1 can optionally further include: a first connector that connects the first circuit board to the base circuit board; and a second connector that connects the second circuit board to the base circuit board.

In Example 3, the circuit system of any one of Examples 1-2 can optionally include wherein the first memory module only has integrated circuit dies connected to one surface of the first circuit board, wherein the second memory module only has integrated circuit dies connected to one surface of the second circuit board, and wherein integrated circuit dies are not in a gap between the first and second circuit boards.

In Example 4, the circuit system of any one of Examples 1-3 can optionally include wherein first conductive pads on a surface of the integrated circuit package for a first channel route first signals to and from the first memory integrated circuit dies, wherein second conductive pads on the surface of the integrated circuit package for a second channel route second signals to and from the second memory integrated circuit dies, and wherein the second signals in the second channel have a reverse orientation through the second conductive pads relative to an orientation of the first signals in the first channel through the first conductive pads.

In Example 5, the circuit system of Example 4 can optionally include wherein the first conductive pads comprise a first group that routes first data signals, a second group that routes first command and address signals, a third group that routes first error correction code signals, and a fourth group that routes second data signals.

In Example 6, the circuit system of Example 5 can optionally include wherein the second conductive pads comprise a fifth group that routes third data signals, a sixth group that routes second error correction code signals, a seventh group that routes second command and address signals, and an eighth group that routes fourth data signals.

In Example 7, the circuit system of Example 6 can optionally include wherein the first conductive pads in the first channel are arranged in a first row, wherein the second conductive pads in the second channel are arranged in a second row, wherein the first conductive pads in the first group and the second conductive pads in the fifth group are arranged in a first column, wherein the first conductive pads in the second group and the second conductive pads in the sixth group are arranged in a second column, wherein the first conductive pads in the third group and the second conductive pads in the seventh group are arranged in a third column, and wherein the first conductive pads in the fourth group and the second conductive pads in the eighth group are arranged in a fourth column.

In Example 8, the circuit system of any one of Examples 1-7 can optionally include wherein the second memory module is parallel to the first memory module, wherein the first and second memory modules are perpendicular to the base circuit board, and wherein the second memory integrated circuit dies face toward the integrated circuit package.

In Example 9, the circuit system of any one of Examples 1-8 can optionally include wherein the main integrated circuit die is a programmable logic integrated circuit die comprising blocks of configurable logic circuits.

Example 10 is a method for using a circuit system, the method comprising: transmitting a first signal between a main integrated circuit die in the circuit system and a first memory integrated circuit die in a first memory module through an integrated circuit package that houses the main integrated circuit die, a base circuit board coupled to the integrated circuit package, and a second circuit board in the first memory module; and transmitting a second signal between the main integrated circuit die and a second memory integrated circuit die in a second memory module through the integrated circuit package, the base circuit board, and a third circuit board in the second memory module, wherein the first and second memory modules are coupled to the base circuit board in the circuit system, and wherein an orientation of the second memory module on the base circuit board is reversed relative to an orientation of the first memory module on the base circuit board such that the second memory integrated circuit die faces away from the first memory integrated circuit die.

In Example 11, the method of Example 10 can optionally include wherein the first memory module only has integrated circuit dies connected to one surface of the second circuit board, wherein the second memory module only has integrated circuit dies connected to one surface of the third circuit board, and wherein the first and second memory modules do not have integrated circuit dies in a gap between the second and third circuit boards.

In Example 12, the method of any one of Examples 10-11 can optionally include wherein transmitting the first signal between the main integrated circuit die in the circuit system and the first memory integrated circuit die in the first memory module further comprises transmitting a first data signal, a first command or address signal, a first error correction code signal, and a second data signal between the main integrated circuit die and the first memory integrated circuit die through conductive pads arranged in a first row of the integrated circuit package, first conductors in the base circuit board, and second conductors in the second circuit board.

In Example 13, the method of Example 12 can optionally include wherein transmitting the second signal between the main integrated circuit die and the second memory integrated circuit die in the second memory module further comprises transmitting a third data signal, a second error correction code signal, a second command or address signal, and a fourth data signal between the main integrated circuit die and the second memory integrated circuit die through conductive pads arranged in a second row of the integrated circuit package, third conductors in the base circuit board, and fourth conductors in the third circuit board.

In Example 14, the method of Example 13 can optionally include wherein the conductive pads that route the first data signal and the third data signal are arranged in a first column, wherein the conductive pads that route the first command or address signal and the second error correction code signal are arranged in a second column, wherein the conductive pads that route the first error correction code signal and the second command or address signal are arranged in a third column, and wherein the conductive pads that route the second data signal and the fourth data signal are arranged in a fourth column on the integrated circuit package.

In Example 15, the method of any one of Examples 10-14 can optionally include wherein the first and second memory modules are positioned in parallel to each other, wherein the first and second memory modules are perpendicular to the base circuit board, and wherein the second memory integrated circuit die faces toward the integrated circuit package.

Example 16 is a circuit system comprising: an integrated circuit package housing a main integrated circuit die; a first memory module comprising a first circuit board, wherein the first memory module only has first memory integrated circuit dies mounted on one surface of the first circuit board; a second memory module comprising a second circuit board, wherein the second memory module only has second memory integrated circuit dies mounted on one surface of the second circuit board; first and second connectors; and a base circuit board connected to the integrated circuit package, to the first memory module through the first connector, and to the second memory module through the second connector, wherein the base circuit board comprises conductors that connect the integrated circuit package to the first and second memory modules, and wherein the second memory integrated circuit dies are facing in an opposite direction relative to a direction that the first memory integrated circuit dies are facing.

In Example 17, the circuit system of Example 16 can optionally include wherein the second memory module has a reverse orientation on the base circuit board relative to the first memory module such that the second memory integrated circuit dies face away from the first memory integrated circuit dies, and the first and second memory integrated circuit dies are not in a gap between the first and second circuit boards.

In Example 18, the circuit system of any one of Examples 16-17 can optionally include wherein first conductive pads on a surface of the integrated circuit package for a first channel route first signals to and from the first memory integrated circuit dies, wherein second conductive pads on the surface of the integrated circuit package for a second channel route second signals to and from the second memory integrated circuit dies, and wherein an order of the second signals in the second channel through the second conductive pads is reversed on the surface of the integrated circuit package relative to an order of the first signals in the first channel through the first conductive pads to accommodate the reverse orientation of the second memory module.

In Example 19, the circuit system of any one of Examples 16-18 can optionally further include: a third memory module comprising a fourth circuit board, wherein the third memory module only has third memory integrated circuit dies mounted on one surface of the fourth circuit board; a fourth memory module comprising a fifth circuit board, wherein the fourth memory module only has fourth memory integrated circuit dies mounted on one surface of the fifth circuit board, wherein the third memory integrated circuit dies are facing in an opposite direction relative to a direction that the fourth memory integrated circuit dies are facing.

In Example 20, the circuit system of Example 19 can optionally include wherein the third memory module has a reverse orientation on the base circuit board relative to the fourth memory module such that the third memory integrated circuit dies face away from the fourth memory integrated circuit dies.

The foregoing description of the exemplary embodiments of the present invention has been presented for the purpose of illustration. The foregoing description is not intended to be exhaustive or to limit the present invention to the examples disclosed herein. In some instances, features of the present invention can be employed without a corresponding use of other features as set forth. Many modifications, substitutions, and variations are possible in light of the above teachings, without departing from the scope of the present invention.

What is claimed is:

1. A circuit system comprising:
an integrated circuit package housing a main integrated circuit die;
a first memory module comprising a first circuit board and first memory integrated circuit dies coupled to the first circuit board;
a second memory module comprising a second circuit board and second memory integrated circuit dies coupled to the second circuit board; and
a base circuit board coupled to the integrated circuit package and to the first and second memory modules, wherein the base circuit board comprises conductors that couple the integrated circuit package to the first and second memory modules, and wherein the second memory module has a reverse orientation on the base circuit board relative to the first memory module such that the second memory integrated circuit dies face away from the first memory integrated circuit dies.

2. The circuit system of claim 1 further comprising:
a first connector that connects the first circuit board to the base circuit board; and
a second connector that connects the second circuit board to the base circuit board.

3. The circuit system of claim 1, wherein the first memory module only has integrated circuit dies mounted on one surface of the first circuit board, wherein the second memory module only has integrated circuit dies mounted on one surface of the second circuit board, and wherein integrated circuit dies are not in a gap between the first and second circuit boards.

4. The circuit system of claim 1, wherein first conductive pads on a surface of the integrated circuit package for a first channel route first signals to and from the first memory integrated circuit dies, wherein second conductive pads on the surface of the integrated circuit package for a second channel route second signals to and from the second memory integrated circuit dies, and wherein the second signals in the second channel have a reverse orientation through the second conductive pads relative to an orientation of the first signals in the first channel through the first conductive pads.

5. The circuit system of claim 4, wherein the first conductive pads comprise a first group that routes first data signals, a second group that routes first command and address signals, a third group that routes first error correction code signals, and a fourth group that routes second data signals.

6. The circuit system of claim 5, wherein the second conductive pads comprise a fifth group that routes third data signals, a sixth group that routes second error correction code signals, a seventh group that routes second command and address signals, and an eighth group that routes fourth data signals.

7. The circuit system of claim 6, wherein the first conductive pads in the first channel are arranged in a first row, the second conductive pads in the second channel are arranged in a second row, wherein the first conductive pads in the first group and the second conductive pads in the fifth group are arranged in a first column, wherein the first conductive pads in the second group and the second conductive pads in the sixth group are arranged in a second column, wherein the first conductive pads in the third group and the second conductive pads in the seventh group are arranged in a third column, and wherein the first conductive pads in the fourth group and the second conductive pads in the eighth group are arranged in a fourth column.

8. The circuit system of claim 1, wherein the second memory module is parallel to the first memory module, wherein the first and second memory modules are perpendicular to the base circuit board, and wherein the second memory integrated circuit dies face toward the integrated circuit package.

9. The circuit system of claim 1, wherein the main integrated circuit die is a programmable logic integrated circuit die comprising blocks of configurable logic circuits.

10. A method for using a circuit system, the method comprising:
transmitting a first signal between a main integrated circuit die in the circuit system and a first memory integrated circuit die in a first memory module through an integrated circuit package that houses the main integrated circuit die, a base circuit board coupled to the integrated circuit package, and a second circuit board in the first memory module; and
transmitting a second signal between the main integrated circuit die and a second memory integrated circuit die in a second memory module through the integrated circuit package, the base circuit board, and a third circuit board in the second memory module,
wherein the first and second memory modules are coupled to the base circuit board in the circuit system, and wherein an orientation of the second memory module on the base circuit board is reversed relative to an orientation of the first memory module on the base circuit board such that the second memory integrated circuit die faces away from the first memory integrated circuit die.

11. The method of claim 10, wherein the first memory module only has integrated circuit dies connected to one surface of the second circuit board, wherein the second memory module only has integrated circuit dies connected to one surface of the third circuit board, and wherein the first and second memory modules do not have integrated circuit dies in a gap between the second and third circuit boards.

12. The method of claim 10, wherein transmitting the first signal between the main integrated circuit die in the circuit system and the first memory integrated circuit die in the first memory module further comprises transmitting a first data signal, a first command or address signal, a first error correction code signal, and a second data signal between the main integrated circuit die and the first memory integrated circuit die through conductive pads arranged in a first row of the integrated circuit package, first conductors in the base circuit board, and second conductors in the second circuit board.

13. The method of claim 12, wherein transmitting the second signal between the main integrated circuit die and the second memory integrated circuit die in the second memory module further comprises transmitting a third data signal, a second error correction code signal, a second command or address signal, and a fourth data signal between the main integrated circuit die and the second memory integrated circuit die through conductive pads arranged in a second row of the integrated circuit package, third conductors in the base circuit board, and fourth conductors in the third circuit board.

14. The method of claim 13, wherein the conductive pads that route the first data signal and the third data signal are arranged in a first column, wherein the conductive pads that route the first command or address signal and the second error correction code signal are arranged in a second column, wherein the conductive pads that route the first error correction code signal and the second command or address signal are arranged in a third column, and wherein the conductive pads that route the second data signal and the fourth data signal are arranged in a fourth column on the integrated circuit package.

15. The method of claim 10, wherein the first and second memory modules are positioned in parallel to each other, wherein the first and second memory modules are perpendicular to the base circuit board, and wherein the second memory integrated circuit die faces toward the integrated circuit package.

16. A circuit system comprising:
an integrated circuit package housing a main integrated circuit die;
a first memory module comprising a first circuit board, wherein the first memory module only has first memory integrated circuit dies mounted on one surface of the first circuit board;
a second memory module comprising a second circuit board, wherein the second memory module only has second memory integrated circuit dies mounted on one surface of the second circuit board;
first and second connectors; and
a base circuit board coupled to the integrated circuit package, to the first memory module through the first connector, and to the second memory module through the second connector, wherein the base circuit board comprises conductors that couple the integrated circuit package to the first and second memory modules, and wherein the second memory integrated circuit dies are facing in an opposite direction relative to a direction that the first memory integrated circuit dies are facing.

17. The circuit system of claim 16, wherein the second memory module has a reverse orientation on the base circuit board relative to the first memory module such that the second memory integrated circuit dies face away from the first memory integrated circuit dies, and the first and second memory integrated circuit dies are not in a gap between the first and second circuit boards.

18. The circuit system of claim 17, wherein first conductive pads on a surface of the integrated circuit package for a first channel route first signals to and from the first memory integrated circuit dies, wherein second conductive pads on the surface of the integrated circuit package for a second channel route second signals to and from the second memory integrated circuit dies, and wherein an order of the second signals in the second channel through the second conductive pads is reversed on the surface of the integrated circuit package relative to an order of the first signals in the first channel through the first conductive pads to accommodate the reverse orientation of the second memory module.

19. The circuit system of claim 16 further comprising:
a third memory module comprising a fourth circuit board, wherein the third memory module only has third memory integrated circuit dies mounted on one surface of the fourth circuit board;
a fourth memory module comprising a fifth circuit board, wherein the fourth memory module only has fourth memory integrated circuit dies mounted on one surface of the fifth circuit board,
wherein the third memory integrated circuit dies are facing in an opposite direction relative to a direction that the fourth memory integrated circuit dies are facing.

20. The circuit system of claim 19, wherein the third memory module has a reverse orientation on the base circuit board relative to the fourth memory module such that the third memory integrated circuit dies face away from the fourth memory integrated circuit dies.
